(19) United States
(12) Patent Application Publication
(10) Pub. No.: US 2026/0299010 A1
(43) Pub. Date: Oct. 1, 2026

(54) MEASUREMENT TEST SYSTEM, CONTROL SYSTEM AND METHOD

(71) Applicant: Rohde & Schwarz GmbH & Co. KG, München (DE)

(72) Inventors: Thomas ROESNER, München (DE); Thomas BRAUNSTORFINGER, München (DE); Sascha LAUMANN, Gröbenzell (DE); Hannes STROBEL, Dorfen/Icking (DE); Volker OHLEN, Pliening (DE); Albert RAMIREZ-PEREZ, München (DE); Andreas WERNER, Chemnitz (DE); Johannes STEFFENS, Rosenheim (DE); Andrew SCHAEFER, Oberhaching (DE)

(21) Appl. No.: 19/544,555

(22) Filed: Feb. 19, 2026

(30) Foreign Application Priority Data
Mar. 27, 2025 (DE) DE102025112012.9

(51) Int. Cl. G01R 31/28; B25J 9/16

(52) U.S. Cl. CPC G01R 31/2844; B25J 9/1679; G01R 31/2837; G01R 31/2849

(57) ABSTRACT

A measurement test system is described comprising one or more device receptacles, each configured to receive an electrical device under test, one or more measurement application devices configured to exchange test signals with the electrical devices under test, a setup device configured to automatically couple the measurement application devices to the electrical devices under test based on corresponding setup instructions, and a control device configured to control the electrical devices under test, or the measurement application devices, or the electrical devices under test and the measurement application devices based on corresponding test instructions, such that a corresponding test of the electrical devices under test is performed, wherein the control device comprises a communication interface and is configured to receive the test instructions via the communication interface. Furthermore, the disclosure relates to a corresponding control system and a corresponding method.

### TECHNICAL FIELD

The present disclosure relates to a measurement test system. Furthermore, the disclosure relates to a corresponding control system and a corresponding method.

### BACKGROUND

The present disclosure is described below in connection with measurement applications. In particular, the present disclosure can be used in the development of electrical devices, but is not limited thereto.

During the development of electrical devices, it is usually necessary to check the functionality of the electrical devices. This can be done, for example, by measuring signals in the electrical devices.

However, a user requires corresponding measurement instruments for this purpose, which require a corresponding laboratory workstation. Furthermore, the user must be trained in the use of the respective measurement application devices.

### SUMMARY

An object of the disclosure is therefore to simplify measurements on electrical devices.

The object is solved by the subject matter of the independent claims.

Disclosed is:

A measurement test system comprising one or more device receptacles, each configured to receive an electrical device under test, and one or more measurement application devices configured to exchange test signals with the electrical devices under test, and a setup device configured to automatically couple the measurement application devices to the electrical devices under test based on corresponding setup instructions, and a control device configured to control the electrical devices under test, or the measurement application devices, or the electrical devices under test and the measurement application devices based on corresponding test instructions, such that a corresponding test of the electrical devices under test is performed, wherein the control device comprises a communication interface and is configured to receive the test instructions via the communication interface.

Further disclosed is:

A control system for controlling a test system according to the present disclosure, wherein the control system comprises a control device configured to manage configuration data concerning the test system, wherein the configuration data identify at least one configuration of the test system, and a user interface configured to output the configuration data and receive user inputs, wherein the user inputs comprise at least test instructions for the test system, and a communication interface configured to transmit the test instructions to the test system.

Further disclosed is:

A method for testing electrical devices under test in a test system, wherein the method comprises outputting configuration data via a user interface coupled in data-communicative connection with the test system, wherein the configuration data identify at least one configuration of the test system, receiving user inputs via the user interface, wherein the user inputs comprise at least test instructions for the test system, receiving one or more electrical devices under test in device receptacles in the test system, automatically coupling one or more measurement application devices of the test system based on corresponding setup instructions to the electrical devices under test, wherein the measurement application devices are configured to exchange test signals with the electrical devices under test, and controlling the electrical devices under test, or the measurement application devices, or the electrical devices under test and the measurement application devices based on the test instructions, wherein the test instructions are received in the test system via a communication interface of a control device of the test system.

The present disclosure is based on the insight that during the development of electrical devices, the necessary measurement application devices are not always available. For example, a user may not have the necessary measurement application devices available on site, or may only have an outdated or unsuitable version of a measurement application device available. It may also be that a user does not have sufficiently large premises to provide a corresponding measurement workstation. Furthermore, high investments may be required for the acquisition of measurement application devices.

The present disclosure therefore provides a system which represents a kind of remote-controlled laboratory, which a user can use anytime and anywhere to carry out corresponding tests with an electrical device.

For this purpose, the user can introduce one or more electrical devices into the measurement test system. The user can, for example, send the electrical devices by mail to an operator of the measurement test system. The operator of the measurement test system can introduce the electrical devices into the measurement test system upon receipt and corresponding tests can then be performed automatically by the measurement test system.

The test system comprises at least one device receptacle for this purpose, wherein multiple device receptacles are possible and individual device receptacles can receive multiple measurement application devices. Each of the device receptacles is configured to receive at least one electrical device under test. “Receiving” is to be understood at least as the respective electrical device being fixed by the device receptacle so that it can be moved in a guided manner with the device receptacle in the test system. Within the scope of this disclosure, the term “electrical device” is to be interpreted broadly. An “electrical device” within the scope of the present disclosure can therefore include any electrical or electronic device that can be contacted by measurement application devices via cable or wirelessly in communicative connection to transmit signals to the electrical device or receive signals from it or measure signals within it. Such electrical devices can comprise analog or digital components or a combination of analog and digital components.

Furthermore, one or more measurement application devices are provided in the test system, which can exchange test signals with the electrical devices under test. “Exchanging” is to be understood as the measurement application devices being able to transmit test signals to the electrical devices under test or receive such signals from the electrical devices under test.

A measurement application device according to the present disclosure can include any device used in a measurement application to capture an input signal or generate an output signal, or performs additional or supporting functions in a measurement application. A measurement application device can also be implemented as a program or software application executed as a measurement application on a computer or processor and capable of communicating with other measurement application devices to accomplish a measurement task. A measurement application, also referred to as a measurement or test setup, can comprise, for example, at least one or several different measurement application devices used for electrical, magnetic, or electromagnetic measurements, particularly on individual devices under test, also called DUT. A measurement application device according to the present disclosure can be configured to perform such electrical, magnetic, or electromagnetic measurements or signal generations, for example, in a measurement laboratory or in a production facility on the respective production line on a device under test. An exemplary measurement setup can serve to qualify the individual devices under test, i.e., to check the proper electrical function of the respective devices under test.

For this purpose, measurement application devices can comprise at least one signal acquisition part for acquiring electrical, magnetic, or electromagnetic signals from the device under test and/or at least one signal generation part for generating electrical, magnetic, or electromagnetic signals that can be supplied to the device under test. Such a signal acquisition part can comprise, for example but not limited to, a front-end stage for acquiring, filtering, attenuating, or amplifying electrical signals. The signal generation part can comprise, for example but not limited to, corresponding signal generators, amplifiers, and filters. In embodiments, signal acquisition via the signal acquisition part is performed in a wired or contact-based manner. For this purpose, a corresponding measurement probe (also called probe) can be connected to the measurement application device via a corresponding cable. Likewise, in embodiments, signal generation and output via the signal generation part is performed in a wired or contact-based manner. For this, a corresponding signal output probe can be connected to the measurement application device via a corresponding cable, or the signal is output directly via the cable, e.g., to a device under test. In further embodiments, signal acquisition can be contactless, e.g., via corresponding antennas, also called OTA or over-the-air. In further embodiments, signal generation and output can be contactless, e.g., via corresponding antennas, also called OTA or over-the-air. A combination of contact-based signal acquisition, contactless signal acquisition, contact-based signal generation and output, and contactless signal generation and output is also possible.

Furthermore, measurement application devices can comprise a signal processing unit during signal acquisition that processes the acquired signals. The processing can include converting the acquired signals from analog to digital signals or vice versa and any other type of digital signal processing, for example converting time-domain to frequency-domain signals.

The measurement application devices can also have a user interface to display the acquired signals to the user and enable the user to control the measurement application devices. Of course, a housing can be provided that encloses the elements of the measurement application device. It is understood that additional elements such as a power supply circuit and communication interfaces can be provided.

A measurement application device can be a standalone device that can be operated in a measurement application without further elements to perform tests on a device under test. Naturally, communication capabilities can also be provided to connect the measurement application device with other measurement application devices.

A measurement application device can be, for example, a signal recording device such as an oscilloscope, particularly a digital oscilloscope, a spectrum analyzer, or a vector network analyzer. A measurement application device can also comprise a signal generation device, e.g., a signal generator, particularly a so-called “arbitrary signal generator”, also referred to as “arbitrary waveform generator”, or a vector signal generator. Further possible measurement application devices include devices such as calibration standards or measurement probe tips.

Of course, at least some of the possible functions, such as signal recording and signal generation, can be combined in a single measurement application device.

In embodiments, the measurement application device can comprise pure data acquisition devices capable of capturing an input signal and transmitting the captured input signal as a digital input signal to a corresponding data storage or application server. Such pure data acquisition devices do not necessarily have a user interface or display. Instead, such pure data acquisition devices can be remotely controlled, e.g., via a corresponding data connection such as a network interface or a USB interface. The same applies to pure signal generation devices that can generate an output signal without having a user interface or configuration input devices. Instead, such signal generation devices can be operated remotely via a data connection.

For handling the electrical devices under test in the device receptacles and the measurement application devices, a setup device is further provided in the test system. The setup device serves to couple the measurement application devices with the electrical devices so that corresponding measurements can be performed. For this purpose, corresponding setup instructions are provided which control the setup device.

The setup device can particularly be an automated mechanical device comprising corresponding actuators, e.g., grippers, to realize a corresponding measurement setup. Coupling the electrical devices with the measurement application devices can be done, for example, via corresponding cables and measurement probes, which can be placed or connected accordingly by the setup device. The setup device can further also position the measurement application devices. The setup of the measurement arrangement, i.e., the coupling of the measurement application devices to the devices under test, is performed based on the setup instructions, which can be provided by a user, e.g., via the communication interface of a control device.

The control device can further control the electrical devices under test and the measurement application devices, so that a predetermined test or a predetermined test sequence is performed in the test system. The definition of the test or test sequence is done by corresponding test instructions. For receiving the test instructions, the control device has a corresponding communication interface.

It is understood that the communication interface can include any type of wired and wireless communication interfaces. Such communication interfaces can have, for example, a network communication interface, particularly an Ethernet, WLAN or WiFi interface, a USB interface, a Bluetooth interface, an NFC interface, and a light-based interface in the visible or non-visible range, particularly an infrared interface, without being limited to these.

The control device can communicate with the measurement application devices and the electrical devices under test via the communication interface. Alternatively or additionally, the control device can comprise a further data interface to communicate with the electrical devices under test and the measurement application devices. The explanations for the communication interface apply analogously to such a further data interface.

Consequently, the test system can be used to test electrical devices under test with the measurement application devices automatically or remotely, without a user having to perform these tests on site themselves.

The test system can thereby be made available to different users who only need to transmit the electrical devices under test to the measurement test system or its operator. Once the electrical devices under test are arranged in the device receptacles, the user can have their tests performed or conduct them remotely via remote control.

To enable the user to control the test system, the present disclosure provides the control system. The control system can be arranged remotely from the test system and be in direct or indirect data-communicative connection with it.

For this purpose, the control system also comprises a communication interface which couples the control system to the test system. Furthermore, the control system comprises a control device which manages configuration data concerning or relating to the test system and setup data or setup instructions. Additionally, a user interface is provided which enables a user to interact with the control system and thereby with the test system.

The communication interface of the control system can include any type of wired and wireless communication interfaces. Such communication interfaces can comprise, for example, a network communication interface, particularly an Ethernet, WLAN or WiFi interface, a USB interface, a Bluetooth interface, an NFC interface, and a light-based interface in the visible or non-visible range, particularly an infrared interface, without being limited to these. The control system can be coupled directly to the test system or, for example, coupled to the test system via the Internet.

The control system can be provided at least partially as a server which is accessible to the user via the Internet. The control device can thus be configured, for example, as a server application executed by a server accessible via a network. Such an application can have, for example, a corresponding API that enables other applications to interact with the application. In such embodiments, a user interface can be configured, for example, as a user application executed on a user's device and communicating with the server or the application on the server via the API. Such an API can have, for example, a SOAP API, a REST API, or a GraphQL API, without being limited to these examples. Such an application can integrate, for example, a web server. The application can also be operated together with a web server on the server. Such a web server can forward requests to the application and return the responses generated by the application. The application can be written, for example, in C, C++, Java, Python, or JavaScript (Node.js), without being limited to these programming languages.

Additionally or alternatively, the application can deliver a user interface as a web-based or HTML-based page, which can be displayed and operated with a browser application on a user's device.

As already explained above, the combination of test system and control system serves to perform automated or remotely controlled tests with the electrical devices.

For this purpose, the control device of the control system manages configuration data for the test system. The configuration data can include, for example:
a listing of the electrical devices under test;
data on configurations of the electrical devices under test;
a listing of the available measurement application devices;
data on configurations of individual measurement application devices;
data on the cabling between the electrical devices under test and the measurement application devices; and
test instructions for performing tests in the test system.

It is understood that the configuration data are not limited to these examples. The configuration data can include any type of data concerning the test system and that may be relevant to the user for test execution or that can be set or adjusted by the user for test execution.

The test instructions can include commands that can be captured and processed by the measurement application devices or the electrical devices under test, so that corresponding tests or test routines are executed. The test instructions for the measurement application devices can be, for example, so-called SCPI instructions (Standard Commands for Programmable Instruments). The test instructions can also include instructions in a programming language, such as C, C++, Python, or JavaScript, which can be interpreted by the respective measurement application device or executed in compiled form. Control of the electrical devices under test can occur via interfaces provided in them and corresponding commands. For example, the electrical devices under test can have a so-called JTAG interface via which they can be controlled, although other interfaces are also possible.

A user can prepare tests to be performed using the control system. For this purpose, the user can list the available measurement application devices via the user interface and define how these are to be connected to the device or devices under test. Furthermore, the user can specify which tests are to be performed, i.e., for example, set corresponding test instructions.

The control system or the control device of the control system can provide functions that allow the user to enter and save this data before the tests are performed. As soon as the electrical device or devices under test arrive at or are available at the test system, the corresponding tests can be performed, particularly automatically.

For prepared tests, the user can be informed by the test system that the electrical devices under test are available and that the tests can now be performed. This can occur, for example, via email or another message type.

The control system can provide a kind of digital twin of the test system. A user can define the configuration, i.e., for example, the selection of measurement application devices, cables, and test functions, on this digital representation of the test system. As described below, this digital representation can also include a digital simulation or representation of the electrical devices under test.

The execution of the tests can also be accompanied and controlled by the user. The user can particularly intervene in the test sequence and modify saved test sequences or perform tests remotely but manually step by step. In such embodiments, the user can also be supported, for example, by additional technical personnel who can control or adjust the test execution via the control system or directly via the measurement test system.

For the joint execution of tests by multiple users or a user with support from additional technical personnel, the control system can provide a collaborative environment that enables the involved persons to jointly enter or edit the configuration data and plan and control the execution of tests. Such a collaborative environment can include, for example, a video conferencing system. A collaborative environment can also be configured as a virtual reality system, as further elaborated below. The test system can further comprise at least one camera providing a video stream that can be displayed to a user.

During or after the execution of the tests, measurement data and results can be presented to the user. Furthermore, the results can be analyzed for errors in the electrical devices under test, and such errors can be displayed to the user. This analysis can occur, for example, in the control device of the control system or in a corresponding additional error analysis unit, which can be coupled to the control system or the test system.

The test system can be operated by an operator, for example, permanently installed in their premises. Alternatively, the test system can, for example, also be installed mobile, e.g., in a container, and provided to the user at a location specified by the user. In such embodiments, the user can introduce the electrical devices under test into the device receptacles themselves.

Since the control system can be made available to multiple users simultaneously, a function can be provided to book the test system. For this purpose, the test system as a whole or parts of the test system that can be used independently in parallel can be provided to users for booking or reservation via a corresponding booking system.

Furthermore, the control system can have an interface to a logistics service provider, enabling a user to generate shipping labels for shipping the electrical devices under test and optionally also arrange collection of the electrical devices under test.

Further embodiments and developments arise from the dependent claims as well as from the description with reference to the figures. In particular, all embodiments mentioned herein can be combined with each other in any order or number, unless individual features are mutually exclusive. In particular, the dependent claims of one claim category can also be developed according to another claim category. Features described as device features can be implemented as corresponding functions of a method and vice versa.

In an embodiment that can be combined with all embodiments mentioned herein, the control device can further be configured to output status information or measured values or both via the communication interface for at least one of the device receptacles, the measurement application devices, the setup device, and the electrical devices under test.

The status information can be current or real-time status information. This is particularly advantageous when the user controls or observes a test themselves.

The status information can also be general status information describing the respective device receptacle, the respective measurement application device, the setup device, or the corresponding electrical device under test. Such status information can be provided to the user, for example, via the control system while the user defines tests for measurement application devices in advance.

The status information can relate to all aspects of the measurement application devices. For example, the status information can relate generally to properties of the measurement application devices, such as the specific device type, the equipment of a measurement application device, and the software or firmware status of a measurement application device.

The status information can also relate to individual configuration options. Such configuration options can concern the measurement application devices generally or also the specific configuration of a component of a measurement application device, such as a signal generation unit or a signal acquisition interface.

A user can not only read the status information but also set it via corresponding test instructions. For example, status information for a measurement application device can indicate that a signal interface and the measurement application device are configured to capture a test signal from an electrical device under test. The user can adjust this configuration via corresponding test instructions so that the configuration meets their requirements.

Thus, test instructions and status information enable interactive configuration of the test system by the user.

The measured values can be any type of values measured in the test system. Such a measurement can particularly be performed by the measurement application devices. Internal measurements in the device receptacles, the setup device, or the electrical devices under test are also possible.

In the control system, such status information and measured values can be provided to the user in a corresponding display in the user interface.

In yet another embodiment that can be combined with all embodiments mentioned herein, the test system can further comprise a cable storage device configured to store cables for coupling the measurement application devices to the electrical devices under test, wherein the setup device can further be configured to retrieve specified cables from the cable storage device and couple the measurement application devices to each other and to the electrical devices under test via the specified cables.

The cable storage device can be, for example, a kind of shelf in which cables can be hung and stored. The cable storage device can be configured or integrated into the setup device such that the cables can be retrieved and deposited in the cable storage device automatically. For this purpose, the cable storage device can have, for example, clamps or rails into which the cables can be hooked.

Such a cable storage device in the test system enables test setups to be built autonomously without user intervention. Particularly when used as a remotely controlled test station, the test system can thus be used by a single user to perform corresponding tests.

In a further embodiment that can be combined with all embodiments mentioned herein, the setup device can further comprise an identification interface configured to read identification features of the cables and select the cables based on the identification features.

The identification features can be provided, for example, in the form of an optical or electrical code. Such codes can be arranged, for example, in barcodes, QR codes, and RFID or NFC tags. The identification interface can correspondingly be configured as an optical or electrical interface. OCR-based text recognition of a cable imprint is also possible.

The identification features can indicate features of the cable, such as its type, its length, a cable attenuation, or the connector types present on the cable. However, the identification features can also merely indicate an ID or identifier of the respective cable. The setup device or the control device can retrieve further information based on the ID or identifier from a corresponding database or from a corresponding server.

Consequently, using the identification features and the identification interface, it becomes possible to identify the cables selected by a user in the corresponding setup instructions or corresponding test instructions and couple the measurement application devices to the electrical devices under test with the specified cables.

In yet another embodiment, which can be combined with all embodiments mentioned herein, the setup device can be configured to transmit the identification features to the control device, and the control device can be configured to control the tests based on the identification features.

The identification features can include, for example, data concerning a cable, particularly calibration data, or the control device can retrieve corresponding data based on the identification features.

Using such data, a test can be adapted accordingly so that the properties of the respective cable are considered. The data can include, for example, the S-parameters for the respective cable. Controlling, e.g., adjusting, a measurement based on the properties of a cable can also be referred to as “de-embedding.” If the data required for de-embedding are provided for the individual cables, active measurement or acquisition of this data can be omitted.

In embodiments, the control device can also be configured to control the setup device such that it connects corresponding calibration standards to corresponding cables or connections in a test setup to perform de-embedding. For this purpose, the measurement application devices can be controlled by the control device to perform the de-embedding when the corresponding calibration standards are connected.

In an embodiment that can be combined with all other embodiments, the setup device or the control device can be configured to output a warning if a specified cable is not available. This enables a user to select alternative cables, particularly if the user is not on site. Furthermore, the user or the operator of the test system can retrofit the missing cables.

In an embodiment that can be combined with all other embodiments, the setup device or the control device can be configured to check whether the measurement application devices are correctly, or at all, coupled to the electrical devices under test. This check can be regarded as a kind of plausibility check to verify whether a measurement is even possible with the current test setup.

For example, it can be automatically checked whether a signal input of a measurement application device is coupled to a signal output of an electrical device under test. It can also be checked whether a measurement application device is coupled to another device in the test setup at all.

If such a check is completed positively, a signal can be output indicating that a test can begin.

In an embodiment that can be combined with all embodiments mentioned herein, the test system can further comprise a signal generator configured to generate and output signals that can be generated by an electrical device under test, and the control device can be configured to control the signal generator based on corresponding test instructions.

The signal generator can be provided in the test system to simulate one or more of the electrical devices under test. For this purpose, the signal generator can be configured via corresponding test instructions to generate and output signals that largely resemble the signals of a real electrical device under test.

Such a signal generator can be provided in the test system, for example, so that a user can remotely prepare tests for an electrical device under test before the electrical device under test is available in the test system.

It is understood that the test results generated with a signal generator may not match the test results of the real electrical device under test. However, the configuration or creation of the tests is thus possible at an early stage.

In a further embodiment that can be combined with all embodiments mentioned herein, the test system can further comprise an environmental adjustment device configured to adjust physical environmental parameters in the test system in a controlled manner, and the control device can be configured to control the environmental adjustment device.

The environmental adjustment device can be configured to adjust, for example, the temperature or humidity in the test system. The environmental adjustment device can therefore be regarded as a kind of climate chamber control module.

Such environmental parameters can also be captured and output via the environmental adjustment device. A user can thus capture, for example, temperature and humidity in the test system and adjust them if necessary.

In yet another embodiment that can be combined with all embodiments mentioned herein, the setup device can further comprise a robot configured to perform the setup of the test system, wherein the robot comprises at least one manipulator holding device configured to detachably hold a manipulator. The manipulator can comprise at least one of a camera, a soldering device, a gripper, a drill, and a measurement probe.

The term “robot” within the scope of this disclosure is to be understood as any possible controlled electromechanical device capable of performing the described functions. Such a robot can be, for example, a kind of plotter with an XY manipulator holding device that can include, as optional components, a camera and lighting. The robot can also be constructed with one or several robot arms, each having multiple degrees of freedom and each comprising a manipulator holding device.

In one embodiment, the manipulator holding device can be permanently coupled to the corresponding manipulator. Alternatively, the manipulator holding device can be detachably coupled to the manipulator. Changing the manipulator can be controlled, for example, via the control device.

The term “manipulator” within the scope of this disclosure includes all elements that can be coupled to the manipulator holding device, regardless of whether they actually enable manipulation.

A possible manipulator can comprise a camera. Such a camera can have a macro function or capture at a 1:1 scale in embodiments. The camera can be infrared-sensitive in embodiments, enabling, for example, detection of heat hotspots. The camera can be configured as a stereo camera or a 3D camera in embodiments. The camera can also be configured as a light field synthesis camera in embodiments.

In further embodiments, the manipulator can comprise various tools. For example, a soldering device can be provided, enabling positioning of a soldering tip, setting a temperature, feeding solder, and extracting soldering fumes.

Furthermore, a kind of drill can be provided to enable drilling. A gripper or pusher can also be provided to enable removing or gripping components.

In another embodiment, the manipulator holding device can be provided on a robot arm. The robot arms can be interchangeable via an arm changer, so that stable, light, short, or long arms can be coupled as needed.

In embodiments, the robot can have a learning-capable control. Such a learning-capable control can, for example, learn a movement sequence from a human or their movement profile. Corresponding AI-supported algorithms can be provided in the learning-capable control. The robot can thus implement human-specified processes or procedures.

Furthermore, sequences can be stored in the control device or the robot's controller, which can be retrieved later. The robot can also be controlled to approach specified positions or positioning markers.

In combination with the control system, data fusion can be performed. In such data fusion, for example, circuit diagrams and layers of a circuit board as well as specified probe positions can be overlaid with graphical representations or videos of a representation or recording of the robot.

In embodiments, multiple robots can be provided, each having one or more fixed or interchangeable manipulators. Such robots can be mobile in the test system, i.e., movable on rails or wheels, for example, or configured as flying robots.

A user can interact with the robot, for example, by observing it in a video. In embodiments, a 3D or AR representation can be provided to the user for remote access to the robot. In embodiments, a kind of “tandem mode” can be provided. In such a mode, the user can observe the robot, and live control or parallel processing can be provided. In this mode, the position of the robot can be determined, for example, via tracking or Real-DOT during the measurement, and corresponding transmission to the user interface can take place.

For controlling the robot, in addition to a VR or AR representation, a corresponding input system, e.g., a joystick or encoder system, or a linkage system, or a glove with sensors, can be provided. Furthermore, pedals for camera positioning can be provided. Feedback can be implemented, for example, via a force feedback system.

In an embodiment that can be combined with all embodiments mentioned herein, the user interface of the control system can comprise a VR interface.

The term “VR interface” within the scope of this disclosure includes any possible display that can show a virtual image, or a combination of a virtual and a captured image, or a captured image of at least a section of the test system. In particular, a VR interface can also include any type of augmented reality display unit that enables the overlay of images of the real world with computer-generated content. Such an augmented reality display unit can display the computer-generated content, for example, on a semi-transparent display into the user's field of view, with the user still seeing their surroundings through the semi-transparent display. Alternatively, the augmented reality display unit can have a non-transparent display in which a video recording of the user's surroundings is displayed and overlaid with the computer-generated content. The augmented reality display unit can be configured, for example, as a kind of glasses worn by a user. The augmented reality display unit can also be configured as a walk-in room with corresponding content displayed on its walls, floors, and/or ceilings. Such systems can also be called “Cave Automatic Virtual Environment,” abbreviated as CAVE. Generally, for this disclosure, the terms virtual reality or VR and augmented reality or AR are to be understood as synonymous or interchangeable.

The VR interface or the control device controlling the VR interface can be configured to display the test system or at least parts of the test system to the user in a VR or AR representation. Simultaneously, input means of the VR interface can allow the user to interact with the virtually represented test system.

Within the scope of the present disclosure, the user can perform all described inputs or interactions either via a conventional user interface, i.e., for example, a PC with corresponding software or a website, or via a VR interface.

If the VR interface is used together with the robot described above, the robot can be represented in the VR interface such that the user can control the robot from an ego perspective, as if they were the robot.

In embodiments, the measurement application devices and the electrical devices under test can be displayed to the user in the VR interface as virtual devices in their actual form. This also applies to the cables. The user can thus set up the test arrangement in virtual reality. This can be done without the test system already adopting this configuration. The configuration can be saved for later execution of tests on the electrical devices under test and later be transmitted to the test system.

The representation of the virtual devices or the virtual test system can, in embodiments, occur simultaneously with the control of the real test system based on the test instructions and corresponding user inputs. In such embodiments, the virtual test system can be continuously adapted to the real test system. The representation of the virtual test system thus always corresponds to the real test system. Inputs made by the user in the virtual test system can be transmitted to the real test system and implemented by it.

In yet another embodiment that can be combined with all embodiments mentioned herein, the control device of the control system can comprise a simulation unit configured to simulate at least a part of the measurement system and perform simulated tests with one or more simulated measurement application devices and one or more simulated devices under test.

Using the simulation unit, a user can use the test system via the control system even when they do not yet have access to the real test system.

The simulation unit enables the user to simulate electrical devices under test and measurement application devices with the associated cabling.

The user can thus completely implement or configure a test setup in the control system and already simulate results from the test setup. This also helps the user to detect errors in the test setup at an early stage before the test setup is transmitted to the test system.

### BRIEF DESCRIPTION OF THE DRAWINGS

The present disclosure is explained in more detail below with reference to the exemplary embodiments indicated in the schematic figures of the drawings.

FIG. 1 shows a block diagram of an embodiment of a test system according to the present disclosure;

FIG. 2 shows a block diagram of another embodiment of a test system according to the present disclosure;

FIG. 3 shows a block diagram of yet another embodiment of a test system according to the present disclosure;

FIG. 4 shows a block diagram of yet another further embodiment of a test system according to the present disclosure;

FIG. 5 shows a block diagram of yet another embodiment of a test system according to the present disclosure;

FIG. 6 shows a block diagram of an embodiment of a control system according to the present disclosure;

FIG. 7 shows a block diagram of another embodiment of a control system according to the present disclosure; and

FIG. 8 shows a flowchart of an embodiment of a method according to the present disclosure.

In all figures, functionally equivalent elements and devices—unless otherwise specified—are labeled with similar reference signs that match at least in the two least significant digits (units and tens).

### DETAILED DESCRIPTION OF THE DRAWINGS

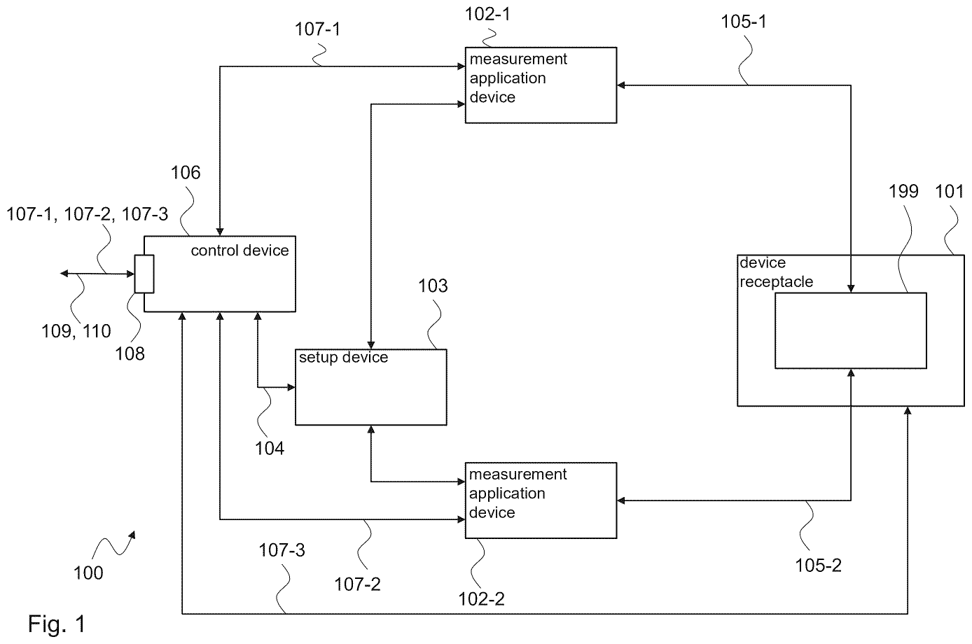

FIG. 1 shows a block diagram of a test system 100. The test system 100 comprises a device receptacle 101, wherein more than one device receptacle is possible. The device receptacle 101 holds an electrical device under test 199. The test system 100 further comprises, by way of example, two measurement application devices 102-1, 102-2, wherein one or more than two measurement application devices are possible. Furthermore, a setup device 103 is provided, which is coupled to a control device 106.

The control device 106 further comprises a communication interface 108. The explanations for further embodiments of the test system presented herein apply analogously to the test system 100.

The setup device 103 can automatically couple the measurement application devices 102-1, 102-2 to the electrical device under test 199 based on corresponding setup instructions 104. The two measurement application devices 102-1, 102-2 serve to exchange test signals 105-1, 105-2 with the electrical device under test 199.

The control device 106 can control the electrical device under test 199 and the measurement application devices 102-1, 102-2 based on corresponding test instructions 107-1, 107-2, such that a corresponding test of the electrical device under test 199 is performed. For this purpose, the test instructions 107-1, 107-2, 107-3 can be received via the communication interface 108.

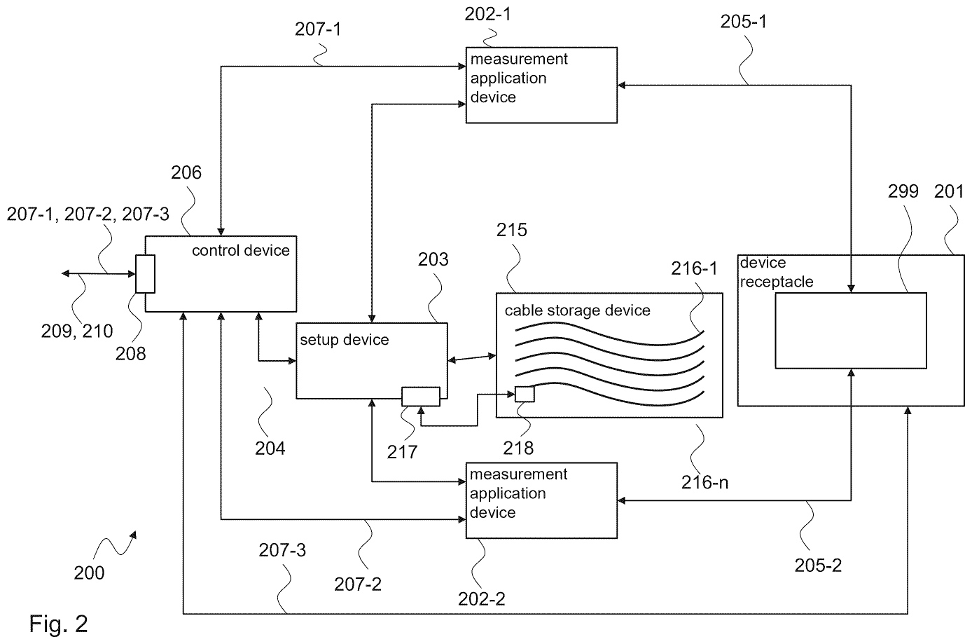

FIG. 2 shows a block diagram of a test system 200. The test system 200 is based on the test system 100. The test system 200 therefore comprises a device receptacle 201, wherein more than one device receptacle is possible. The device receptacle 201 holds an electrical device under test 299. Furthermore, the test system 200 comprises, by way of example, two measurement application devices 202-1, 202-2, wherein one or more than two measurement application devices are possible. Furthermore, a setup device 203 is provided, which is coupled to a control device 206. The control device 206 further comprises a communication interface 208. The explanations for further embodiments of the test system presented herein apply analogously to the test system 200.

The test system 200 further comprises a cable storage device 215. The cable storage device 215 can removably receive or store cables 216-1-216-n for coupling the measurement application devices 202-1, 202-2 to the electrical device under test 299.

The setup device 203 can retrieve specified cables 216-1-216-n from the cable storage device 215 and couple the measurement application devices 202-1, 202-2 to each other and to the electrical device under test 299 via the specified cables 216-1 216-n. For this purpose, the setup device 203 can be mechanically constructed accordingly, i.e., comprise actuators such as movable grippers.

In embodiments, the cable storage device 215 can be configured, for example, as a kind of automated magazine. Such a magazine can be integrated into the setup device 203 or implemented as a separate element.

The setup device 203 can comprise an identification interface 217. The individual cables 216-1-216-n can comprise corresponding identification features 218. The setup device 203 can read these identification features 218 via the identification interface 217 and select the cables 216-1-216-n based on the identification features 218.

The setup device 203 can further transmit the identification features 218 to the control device 206. The control device 206 can then control the tests based on the identification features 218, and e.g., perform corresponding de-embedding. In embodiments, the identification interface 217 can also be arranged at or in the control device 206.

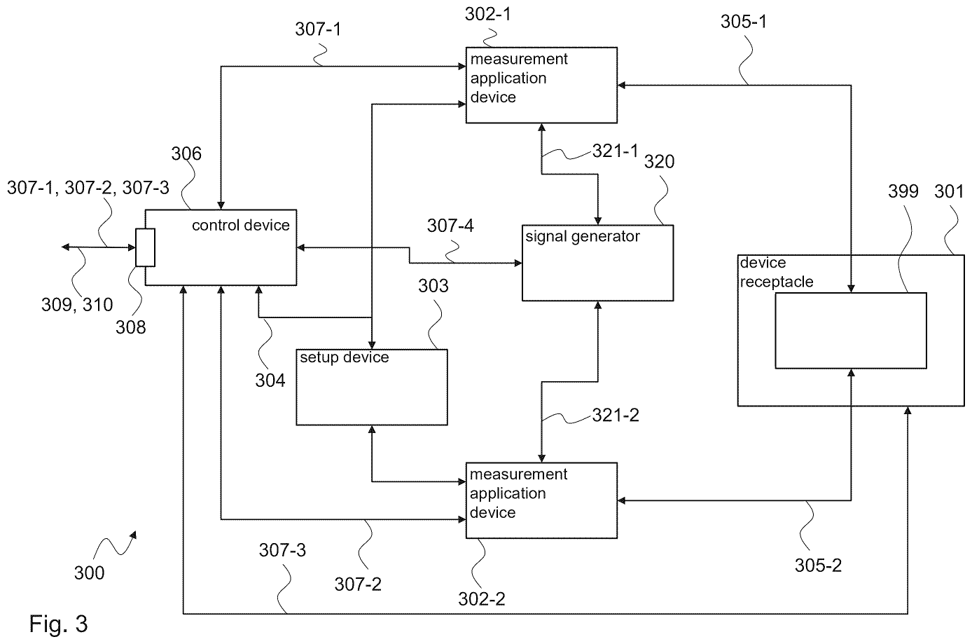

FIG. 3 shows a block diagram of a test system 300. The test system 300 is based on the test system 100. The test system 300 therefore comprises a device receptacle 301, wherein more than one device receptacle is possible. The device receptacle 301 holds an electrical device under test 399. Furthermore, the test system 300 comprises, by way of example, two measurement application devices 302-1, 302-2, wherein one or more than two measurement application devices are possible. Furthermore, a setup device 303 is provided, which is coupled to a control device 306. The control device 306 further comprises a communication interface 308. The explanations for further embodiments of the test system presented herein apply analogously to the test system 300.

The test system 300 further comprises a signal generator 320. The signal generator 320 can generate and output simulated signals 321-1, 321-2 that can be generated by an electrical device under test 399, particularly to the measurement application devices 302-1, 302-2. The control device 306 can control the signal generator 320 based on corresponding test instructions 307-4.

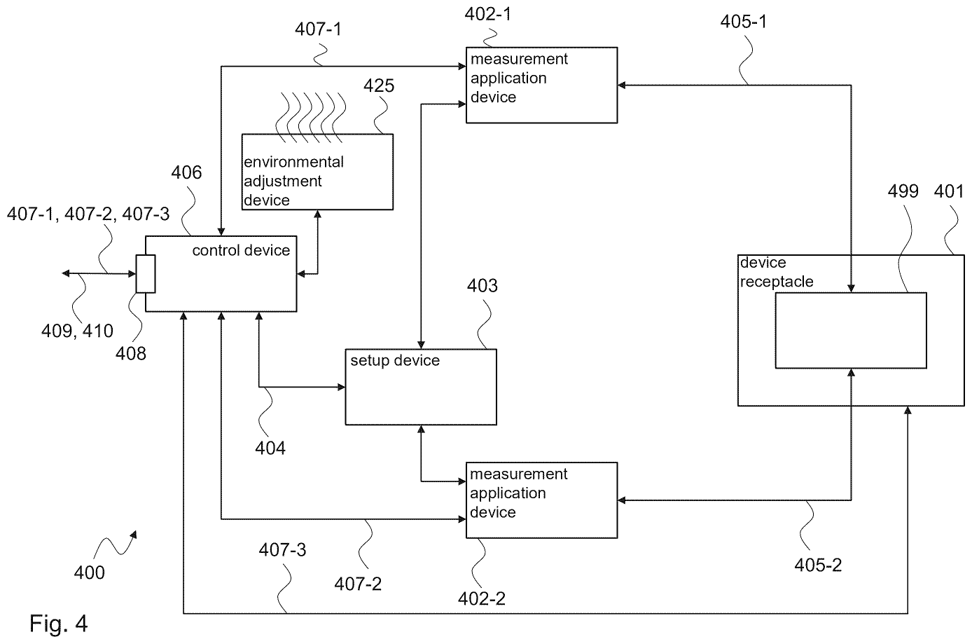

FIG. 4 shows a block diagram of a test system 400. The test system 400 is based on the test system 100. The test system 400 therefore comprises a device receptacle 401, wherein more than one device receptacle is possible. The device receptacle 401 holds an electrical device under test 499. Furthermore, the test system 400 comprises, by way of example, two measurement application devices 402-1, 402-2, wherein one or more than two measurement application devices are possible. Furthermore, a setup device 403 is provided, which is coupled to a control device 406. The control device 406 further comprises a communication interface 408. The explanations for further embodiments of the test system presented herein apply analogously to the test system 400.

The test system 400 further comprises an environmental adjustment device 425. The environmental adjustment device 425 can adjust physical environmental parameters, e.g., a temperature, in the test system 400 in a controlled manner. For this purpose, the environmental adjustment device 425 can comprise, for example, a heater or an air conditioning unit. The control device 406 can control the environmental adjustment device 425 accordingly. In embodiments, the environmental adjustment device 425 can be configured to control any further parameters, such as humidity, in the test system.

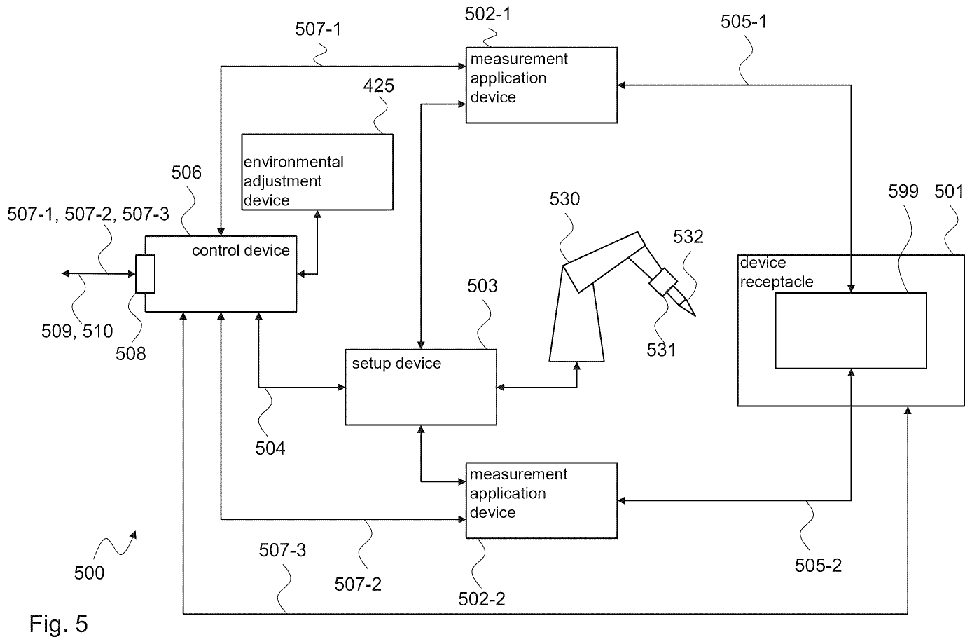

FIG. 5 shows a block diagram of a test system 500. The test system 500 is based on the test system 100. The test system 500 therefore comprises a device receptacle 501, wherein more than one device receptacle is possible. The device receptacle 501 holds an electrical device under test 599. Furthermore, the test system 500 comprises, by way of example, two measurement application devices 502-1, 502-2, wherein one or more than two measurement application devices are possible. Furthermore, a setup device 503 is provided, which is coupled to a control device 506. The control device 506 further comprises a communication interface 508. The explanations for further embodiments of the test system presented herein apply analogously to the test system 500.

The setup device 503 of test system 500 further comprises a robot 530 that can perform the setup of the test system 500. Setup particularly refers to the coupling of the measurement application devices 502-1, 502-2 to the electrical device under test 599 as described herein. Furthermore, the setup can also include the positioning of individual elements of the test system 500 or the electrical device under test 599, without being limited thereto.

The robot 530 can also perform further actions not directly related to the setup of the test system 500. For example, the robot 530 can process the electrical device under test 599.

The robot 530 can comprise at least one manipulator holding device 531. This can detachably hold a manipulator 532. Possible manipulators 532 can be: a camera, a soldering device, a gripper, a drill, and a measurement probe, but are not limited thereto.

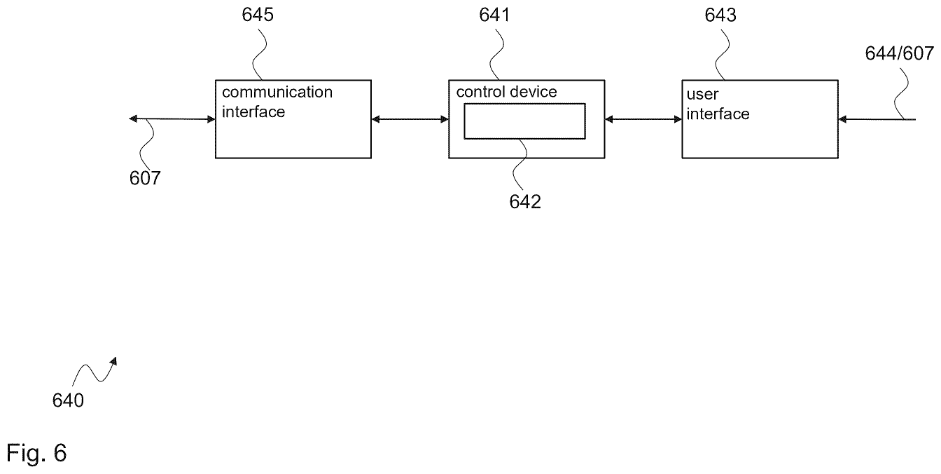

FIG. 6 shows a block diagram of a control system 640. The control system 640 serves to control a test system according to the present disclosure and can be coupled to it, e.g., via a network. The control system 640 comprises a control device 641 coupled to a user interface 643 and a communication interface 645. The explanations for further embodiments of the control system presented herein apply analogously to the control system 640.

The control device 641 can manage configuration data 642 concerning the test system, i.e., at least store and output it. The configuration data 642 identify at least one configuration of the test system. The user interface 643 can output the configuration data 642 to a user and receive user inputs 644 from them. The user inputs 644 can comprise at least test instructions 607 for the test system. The test instructions 607 can be transmitted to the test system via the communication interface 645.

In embodiments, the user interface 643 can be a VR interface, as described in more detail above.

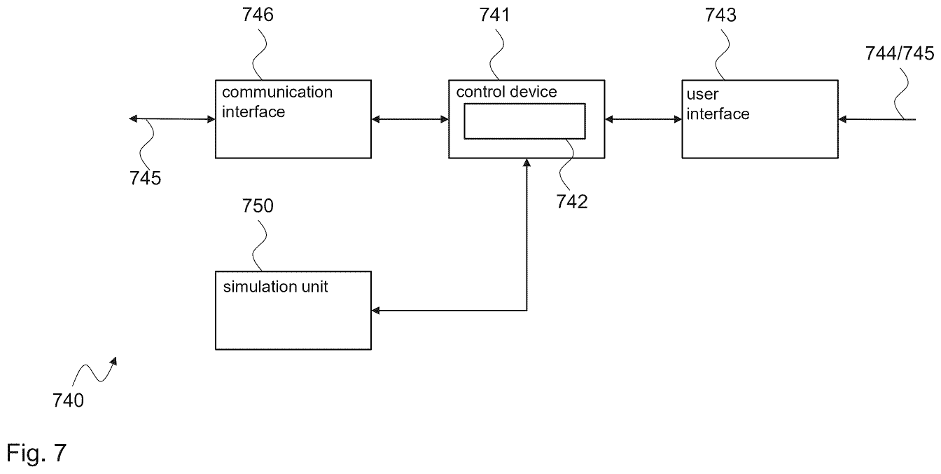

FIG. 7 shows a block diagram of a control system 740. The control system 740 is based on the control system 740. The control system 740 therefore comprises a control device 741 coupled to a user interface 743 and a communication interface 745. The explanations for further embodiments of the control system presented herein apply analogously to the control system 740.

In the control system 740, the control device 741 is coupled to a simulation unit 750. The simulation unit 750 can also be integrated into the control device 741.

The simulation unit 750 can simulate at least a part of the measurement system and perform simulated tests with one or more simulated measurement application devices and one or more simulated devices under test.

For this purpose, the simulation unit 750 can execute, for example, a corresponding computer program or several computer programs serving to simulate electrical elements. The simulation unit 750 can be configured as a corresponding computing device which loads and executes the computer programs from a memory.

The computing device can comprise a dedicated processing element or be provided as part of one, for example as a processing unit, microcontroller, Field-Programmable Gate Array (FPGA), Complex Programmable Logic Device (CPLD), Application Specific Integrated Circuit (ASIC) or similar. A corresponding program or configuration can be provided to implement the required functionality. The computing device can also be provided at least partially as a non-volatile computer program product containing computer-readable instructions executable by a processing element. In a further embodiment, the computing device can be integrated as an additional function or method into the firmware or operating system of a processing element already present in the respective application, e.g., the control device 741, with the corresponding computer-readable instructions being provided. Such computer-readable instructions can be stored in a memory coupled to or integrated into the processing element. The processing element can load and execute the computer-readable instructions from the memory.

Generally, any computer program or computer program product disclosed herein is to be understood as a non-volatile computer program product.

For easier understanding, the reference signs for FIGS. 1-7 are retained as a reference in the following description.

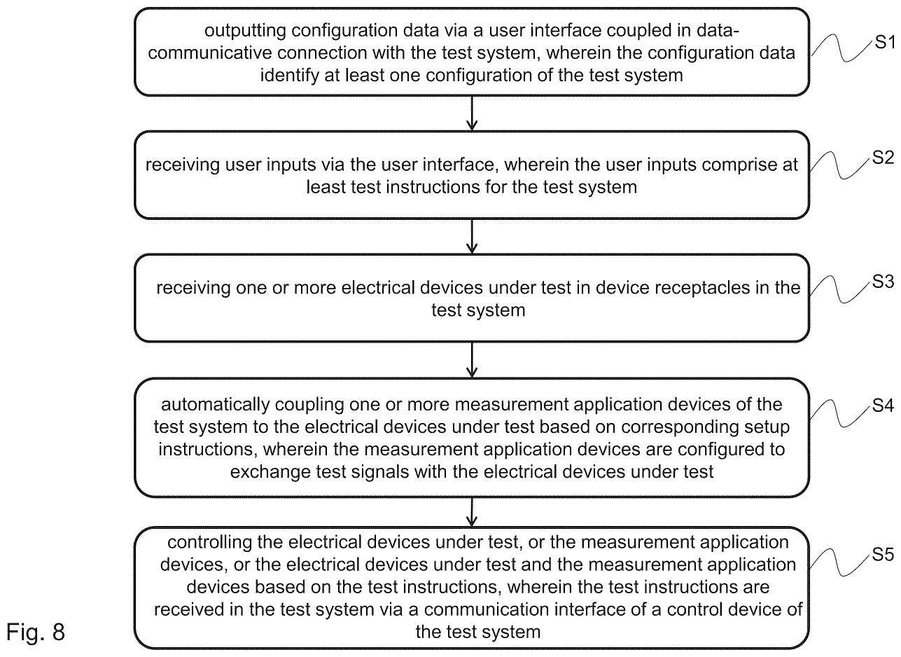

FIG. 8 shows a flowchart of a method for testing electrical devices under test 199, 299, 399, 499, 599, 699 in a test system 100, 200, 300, 400, 500.

The method comprises: outputting S1 configuration data 642, 742 via a user interface 643, 743 coupled in data-communicative connection with the test system 100, 200, 300, 400, 500, wherein the configuration data 642, 742 identify at least one configuration of the test system 100, 200, 300, 400, 500, receiving S2 user inputs 644, 744 via the user interface 643, 743, wherein the user inputs 644, 744 comprise at least test instructions 107-1, 107-2, 107-3, 207-1, 207-2, 207-3, 307-1, 307-2, 307-3, 307-4, 407-1, 407-2, 407-3, 507-1, 507-2, 507-3, 607 for the test system 100, 200, 300, 400, 500, receiving S3 one or more electrical devices under test 199, 299, 399, 499, 599, 699 in device receptacles 101, 201, 301, 401, 501, 601 in the test system 100, 200, 300, 400, 500, automatically S4 coupling one or more measurement application devices 102-1, 102-2, 202-1, 202-2, 302-1, 302-2, 402-1, 402-2, 502-1, 502-2 of the test system 100, 200, 300, 400, 500 based on corresponding setup instructions 104, 204, 304, 404, 504, 604 to the electrical devices under test 199, 299, 399, 499, 599, 699, wherein the measurement application devices 102-1, 102-2, 202-1, 202-2, 302-1, 302-2, 402-1, 402-2, 502-1, 502-2 are configured to exchange test signals 105-1, 105-2, 205-1, 205-2, 305-1, 305-2, 405-1, 405-2, 505-1, 505-2 with the electrical devices under test 199, 299, 399, 499, 599, 699, and controlling S5 the electrical devices under test 199, 299, 399, 499, 599, 699, or the measurement application devices 102-1, 102-2, 202-1, 202-2, 302-1, 302-2, 402-1, 402-2, 502-1, 502-2, or the electrical devices under test 199, 299, 399, 499, 599, 699 and the measurement application devices 102-1, 102-2, 202-1, 202-2, 302-1, 302-2, 402-1, 402-2, 502-1, 502-2 based on the test instructions 107-1, 107-2, 107-3, 207-1, 207-2, 207-3, 307-1, 307-2, 307-3, 307-4, 407-1, 407-2, 407-3, 507-1, 507-2, 507-3, 607, wherein the test instructions 107-1, 107-2, 107-3, 207-1, 207-2, 207-3, 307-1, 307-2, 307-3, 307-4, 407-1, 407-2, 407-3, 507-1, 507-2, 507-3, 607 are received in the test system 100, 200, 300, 400, 500 via a communication interface 108, 208, 308, 408, 508, 608 of a control device 106, 206, 306, 406, 506, 606 of the test system 100, 200, 300, 400, 500.

In embodiments, the method can further comprise storing cables 216-1-216-n for coupling the measurement application devices 102-1, 102-2, 202-1, 202-2, 302-1, 302-2, 402-1, 402-2, 502-1, 502-2 to the electrical devices under test 199, 299, 399, 499, 599, 699 in a cable storage device 215 of the test system 100, 200, 300, 400, 500, and automatically retrieving specified cables 216-1-216-n from the cable storage device 215, wherein the measurement application devices 102-1, 102-2, 202-1, 202-2, 302-1, 302-2, 402-1, 402-2, 502-1, 502-2 are automatically coupled to each other and to the electrical devices under test 199, 299, 399, 499, 599, 699 via the specified cables 216-1-216-n.

The method can further comprise generating and outputting signals 321-1, 321-2 generatable by an electrical device under test 199, 299, 399, 499, 599, 699 based on corresponding test instructions 107-1, 107-2, 107-3, 207-1, 207-2, 207-3, 307-1, 307-2, 307-3, 307-4, 407-1, 407-2, 407-3, 507-1, 507-2, 507-3, 607 with a signal generator 320 of the test system 100, 200, 300, 400, 500.

When performing the method, the receiving of one or more electrical devices under test 199, 299, 399, 499, 599, 699 in device receptacles 101, 201, 301, 401, 501, 601, and/or the automatic coupling can be executed with a robot 530. This can comprise at least one manipulator holding device 531 configured to detachably hold a manipulator 532.

The manipulator 532 can comprise at least one of a camera, a soldering device, a gripper, a drill, and a measurement probe.

The processes, methods, or algorithms disclosed herein can be transferred to or implemented by a computing unit, controller, or computer. These can include any existing programmable electronic control unit or dedicated electronic control unit. Likewise, the processes, methods, or algorithms can be stored as data and instructions executable by a controller or computer in many forms, including but not limited to, information permanently stored on non-writable storage media such as ROM devices, and information alterably stored on writable storage media such as floppy disks, magnetic tapes, CDs, RAM memory, and other magnetic and optical media. The processes, methods, or algorithms can also be implemented in a software-executable object. Alternatively, the processes, methods, or algorithms can be embedded wholly or partially in suitable hardware components such as application-specific integrated circuits (ASICs), Field-Programmable Gate Arrays (FPGAs), state machines, controllers, or other hardware components or devices, or a combination of hardware, software, and firmware components.

Although exemplary embodiments have been described above, it is understood that these embodiments do not encompass all possible forms of implementations of the present disclosure covered by the claims. The terms used in the specification are for description and not limitation, and it is understood that various modifications can be made without departing from the spirit and scope of the disclosure. As described previously, features of various embodiments can be combined to form further embodiments of the invention that may not be explicitly described or illustrated. While various embodiments may be described as advantageous or preferred over other embodiments or implementations of the prior art with respect to one or more desired characteristics, those skilled in the art recognize that one or more features or characteristics may be modified to favor desired overall system attributes depending on the specific application and implementation. These attributes can include cost, strength, durability, life cycle cost, marketability, appearance, packaging, size, serviceability, weight, manufacturability, ease of assembly, etc., but are not limited to these examples. To the extent that embodiments are described as less desirable than other embodiments or implementations of the prior art with respect to certain characteristics, such embodiments nevertheless fall within the scope of the disclosure and may be desirable for particular applications.

Regarding the processes, systems, methods, heuristics, etc., described herein, it is understood that although the steps of such processes, etc., have been described in a specific sequence, such processes may also be performed in a sequence different from that described herein. Likewise, it is understood that certain steps may be performed concurrently, that other steps may be added, or that certain steps described herein may be omitted. In other words, the descriptions of the processes herein are provided to illustrate certain embodiments and should in no way be construed as limiting the claims.

In summary, it is understood that the disclosed subject matter may be modified and varied without departing from the scope of the present disclosure.

All terms used in the claims are intended to be given their broadest reasonable constructions and their ordinary meanings as understood by those knowledgeable in the technologies described herein, unless an explicit indication to the contrary is made. In particular, the use of singular articles such as “a,” “the,” “said,” etc., should be read to recite one or more of the indicated elements unless a claim expressly states otherwise.

### REFERENCE SIGN LIST

100, 200, 300, 400, 500 measurement test system
101, 201, 301, 401, 501, 601 device receptacle
102-1, 102-2, 202-1, 202-2, 302-1, 302-2 measurement application device
402-1, 402-2, 502-1, 502-2 measurement application device
103, 203, 303, 403, 503 setup device
104, 204, 304, 404, 504, 604 setup instruction
105-1, 105-2, 205-1, 205-2, 305-1, 305-2 test signal
405-1, 405-2, 505-1, 505-2 test signal
106, 206, 306, 406, 506, 606 control device
107-1, 107-2, 107-3, 207-1, 207-2, 207-3 test instruction
307-1, 307-2, 307-3, 307-4, 407-1, 407-2, 407-3 test instruction
507-1, 507-2, 507-3, 607 test instruction
108, 208, 308, 408, 508, 608 communication interface
109, 209, 309, 409, 509, 609 status information
110, 210, 310, 410, 510, 610 measured value
215 cable storage device
216-1-216-n cable
217 identification interface
218 identification feature
320 signal generator
321-1, 321-2 signal
425 environmental adjustment device
530 robot
531 manipulator holding device
532 manipulator
640, 740 control system
641, 741 control device
642, 742 configuration data
643, 743 user interface
644, 744 user inputs
645, 745 communication interface
750 simulation unit
199, 299, 399, 499, 599, 699 electrical device
S1-S5 method steps

1. A measurement test system comprising:
one or more device receptacles, each configured to receive an electrical device under test ;
one or more measurement application devices configured to exchange test signals with the electrical device under test;
a setup device configured to automatically couple the measurement application devices to the electrical device under test based on corresponding setup instructions; and
a control device configured to control the electrical device under test, or the measurement application devices, or the electrical device under test and the measurement application devices based on corresponding test instructions, such that a corresponding test of the electrical device under test is performed;
wherein the control device comprises a communication interface and is configured to receive the test instructions via the communication interface.

2. The measurement test system according to claim 1, wherein the control device is further configured to output status information or measured values or both via the communication interface for at least one of:
the device receptacles;
the measurement application devices;
the setup device; or
the electrical device under test.

3. The measurement test system according to claim 1, further comprising a cable storage device configured to store cables for coupling the measurement application devices to the electrical device under test ;
wherein the setup device is further configured to retrieve specified cables from the cable storage device and couple the measurement application devices to each other and to the electrical device under test via the specified cables.

4. The measurement test system according to claim 3, wherein the setup device further comprises an identification interface configured to read identification features of the cables and select the cables based on the identification features.

5. The measurement test system according to claim 4, wherein the setup device is configured to transmit the identification features to the control device; and
wherein the control device is configured to control the tests based on the identification features.

6. The measurement test system according to claim 1, further comprising a signal generator configured to generate and output signals generatable by an electrical device under test;
wherein the control device is configured to control the signal generator based on corresponding test instructions.

7. The measurement test system according to claim 1, further comprising an environmental adjustment device configured to adjust physical environmental parameters in the test system in a controlled manner;
wherein the control device is configured to control the environmental adjustment device.

8. The measurement test system according to claim 1, wherein the setup device further comprises a robot configured to perform the setup of the test system;
wherein the robot comprises at least one manipulator holding device configured to detachably hold a manipulator;
wherein the manipulator comprises at least one of:
a camera;
a soldering device;
a gripper;
a drill; or
a measurement probe.

9. A control system for controlling a test system according to claim 1, wherein the control system comprises:
a control device configured to manage configuration data concerning the test system, wherein the configuration data identify at least one configuration of the test system;
a user interface configured to output the configuration data and receive user inputs, wherein the user inputs comprise at least test instructions for the test system; and
a communication interface configured to transmit the test instructions to the test system.

10. The control system according to claim 9, wherein the user interface comprises a VR interface.

11. The control system according to claim 9, wherein the control device comprises a simulation unit configured to simulate at least a part of the measurement system and perform simulated tests with one or more simulated measurement application devices and one or more simulated devices under test.

12. A method for testing electrical devices under test in a test system, wherein the method comprises:
outputting configuration data via a user interface coupled in data-communicative connection with the test system, wherein the configuration data identifies at least one configuration of the test system;
receiving user inputs via the user interface, wherein the user inputs comprise at least test instructions for the test system;
receiving one or more electrical devices under test in device receptacles in the test system;
automatically coupling one or more measurement application devices of the test system to the electrical devices under test based on corresponding setup instructions, wherein the measurement application devices are configured to exchange test signals with the electrical devices under test; and
controlling the electrical devices under test, or the measurement application devices, or the electrical devices under test and the measurement application devices based on the test instructions, wherein the test instructions are received in the test system via a communication interface of a control device of the test system.

13. A method according to claim 12, further comprising:
storing cables for coupling the measurement application devices to the electrical devices under test in a cable storage device of the test system;
automatically retrieving specified cables from the cable storage device; and
automatically coupling the measurement application devices to each other and to the electrical devices under test via the specified cables.

14. A method according to claim 12, further comprising generating and outputting signals generatable by an electrical device under test based on corresponding test instructions with a signal generator of the test system.

15. The method according to claim 12, wherein at least one of:
receiving one or more electrical devices under test in device receptacles, and automatically coupling is executed with a robot comprising at least one manipulator holding device configured to detachably hold a manipulator;
wherein the manipulator comprises at least one of:
a camera;
a soldering device;
a gripper;
a drill; or
a measurement probe.
